(19) United States
(12) Patent Application Publication
(10) Pub. No.: US 2026/0260678 A1
(43) Pub. Date: Sep. 3, 2026

(54) SEMICONDUCTOR APPARATUS HAVING A CLOCK DISTRIBUTION NETWORK

(71) Applicant: SK hynix Inc., Icheon-si Gyeonggi-do (KR)

(72) Inventors: Gyeong Ha RYU, Icheon-si Gyeonggi-do (KR); Hyun Kyu PARK, Icheon-si Gyeonggi-do (KR)

(73) Assignee: SK hynix Inc., Icheon-si Gyeonggi-do (KR)

(21) Appl. No.: 19/224,298

(22) Filed: May 30, 2025

(30) Foreign Application Priority Data
Feb. 28, 2025 (KR) 10-2025-0027073

(51) Int. Cl. G11C 7/22; G11C 8/18

(52) U.S. Cl. CPC G11C 7/222; G11C 8/18

(57) ABSTRACT

A semiconductor apparatus includes a clock distribution network, wherein a clock receiving circuit receives a first data clock signal and a second data clock signal to generate a first internal clock signal pair and a second internal clock signal pair. A first clock distribution path provides the first internal clock signal pair to a data receiving circuit, and the data receiving circuit divides the first internal clock signal pair to generate a plurality of write clock signals. A second clock distribution path divides the second internal clock signal pair to generate a plurality of read clock signals and provides the plurality of read clock signals to a data output circuit.

### CROSS- REFERENCE TO RELATED APPLICATION

The present application claims priority under 35 U.S.C. § 119(a) to Korean application number 10-2025-0027073 filed on Feb. 28, 2025, in the Korean Intellectual Property Office, which application is incorporated herein by reference in its entirety.

### BACKGROUND

### 1. Technical Field

Various embodiments generally relate to integrated circuit technology, and more particularly, to a semiconductor apparatus having a clock distribution network.

### 2. Related Art

An electronic device includes many electronic elements. A computer system, for example, includes many semiconductor apparatuses each configured by a semiconductor. The semiconductor apparatuses constituting a computer system may communicate with each other by transmitting and receiving clock signals and data. A semiconductor apparatus can operate in synchronization with a clock signal. As the operating speed of the computer system and the frequency of the system clock signal increase, the pulse width of the system clock signal decreases, and the setup and hold margins for synchronizing the data signal to the system clock signal decrease.

A semiconductor apparatus such as a memory device may generate a plurality of internal clock signals with different phases by dividing the system clock signal to increase the setup and hold margins for synchronizing the data signal. The semiconductor apparatus may synchronize the data signal in synchronization with each of the plurality of internal clock signals to increase the margin for sampling the data signal. Therefore, it is necessary to maintain a constant phase difference between the plurality of internal clock signals for the operational reliability of the semiconductor apparatus. However, the phase difference between the plurality of internal clock signals may change due to various factors. In particular, the plurality of internal clock signals may propagate through various internal paths of the semiconductor apparatus, and a skew and/or variation may occur in the phase difference between the plurality of internal clock signals.

### SUMMARY

In an embodiment, a semiconductor apparatus may include a clock receiving circuit, a first clock distribution circuit, a second clock distribution circuit, a first data receiving circuit, and a first data output. The clock receiving circuit may be configured to receive a first data clock signal and a second data clock signal, and may be configured to generate a first internal clock signal pair and a second internal clock signal pair. The first clock distribution circuit may be configured to transmit the first internal clock signal pair. The second clock distribution circuit may be configured to divide a frequency of the second internal clock signal pair to generate a plurality of read clock signals, and may be configured to transmit the plurality of read clock signals. The first data receiving circuit may be configured to receive the first internal clock signal pair from the first clock distribution circuit, may be configured to divide a frequency of the first internal clock signal pair to generate a first plurality of write clock signals, and may be configured to receive first data in synchronization with the first plurality of write clock signals. The first data output circuit may be configured to receive the plurality of read clock signals from the second clock distribution circuit, and may be configured to output the first data based on the plurality of read clock signals.

In an embodiment, a semiconductor apparatus may include a clock receiving circuit, a first clock distribution circuit, a first data receiving circuit, and a second data receiving circuit. The clock receiving circuit may be configured to receive a first data clock signal and a second data clock signal, and may be configured to generate a first internal clock signal pair and a second internal clock signal pair. The first clock distribution circuit may be configured to transmit the first internal clock signal pair. The first data receiving circuit may be configured to receive the first internal clock signal pair from the first clock distribution circuit, may be configured to divide a frequency of the first internal clock signal pair to generate a first plurality of write clock signals, and may be configured to receive first data based on the first plurality of write clock signals. The second data receiving circuit may be configured to receive the first internal clock signal pair from the first clock distribution circuit, may be configured to divide a frequency of the first internal clock signal pair to generate a second plurality of write clock signals, and may be configured to receive second data based on the second plurality of write clock signals.

In an embodiment, a semiconductor apparatus may include a clock receiving circuit, a reset control circuit, a clock divider, and an initial level setting circuit. The clock receiving circuit may be configured to receive a first data clock signal and a second data clock signal, and may be configured to generate an internal clock signal and a complementary internal clock signal. The reset control circuit may be configured to generate a divider enable signal based on an enable signal and the complementary internal clock signal, and may be configured to generate a first gating clock signal and a second gating clock signal from the internal clock signal and the complementary internal clock signal when the divider enable signal is enabled. The clock divider may be configured to generate a first divided clock signal, a second divided clock signal, a third divided clock signal, and a fourth divided clock signal, each having a lower frequency than the first and second gating clock signals, based on the first and second gating clock signals. The initial level setting circuit may be configured to set logic levels of the first to fourth divided clock signals based on the divider enable signal

In an embodiment, a clock buffer, a first clock driver circuit, a second clock driver circuit, a first clock distribution circuit, and a second clock distribution circuit. The clock buffer may be configured to differentially amplify a first data clock signal and a second data clock signal to generate a first buffered clock signal and a second buffered clock signal. The first clock driver circuit may be configured to set a first internal clock signal pair to different logic levels based on a write signal, and may be configured to change logic levels of the first internal clock signal pair according to logic levels of the first and second buffered clock signals after the first and second buffered clock signals toggle at least once. The second clock driver circuit may be configured to change logic levels of a second internal clock signal pair according to logic levels of the first and second buffered clock signals based on a read signal. The first clock distribution circuit may be configured to distribute the first internal clock signal pair to a plurality of data receiving circuits. The second clock distribution circuit may be configured to divide the second internal clock signal pair to generate a plurality of read clock signals, and may be configured to distribute the plurality of read clock signals to a plurality of data output circuits.

### BRIEF DESCRIPTION OF THE DRAWINGS

FIG. 1 is a diagram illustrating a configuration of a semiconductor apparatus and a clock distribution network according to an embodiment of the present disclosure.

FIG. 2 is a diagram illustrating a configuration of a first write clock divider circuit shown in FIG. 1.

FIG. 3 is a diagram illustrating a configuration of a read clock divider circuit shown in FIG. 1.

FIG. 4 is a diagram illustrating a configuration of a phase adjustment circuit shown in FIG. 3.

FIG. 5 is a diagram illustrating a configuration of a clock divider circuit according to an embodiment of the present disclosure.

FIG. 6 is a diagram illustrating a configuration of a reset control circuit shown in FIG. 5.

FIG. 7 is a diagram illustrating a configuration of a clock divider shown in FIG. 5.

FIG. 8 is a diagram illustrating a configuration of an initial level setting circuit shown in FIG. 5.

FIG. 9 is a timing diagram illustrating an operation of a clock divider circuit according to an embodiment of the present disclosure.

FIG. 10 is a diagram illustrating a configuration of a clock receiving circuit shown in FIG. 1.

FIG. 11 is a diagram illustrating a configuration of a write clock driver circuit shown in FIG. 10.

FIG. 12 is a diagram illustrating a configuration of an enable control circuit shown in FIG. 11.

FIG. 13 is a timing diagram illustrating an operation of a clock receiving circuit according to an embodiment of the present disclosure.

FIG. 14 is a diagram illustrating a configuration of a semiconductor system according to an embodiment of the present disclosure.

### DETAILED DESCRIPTION

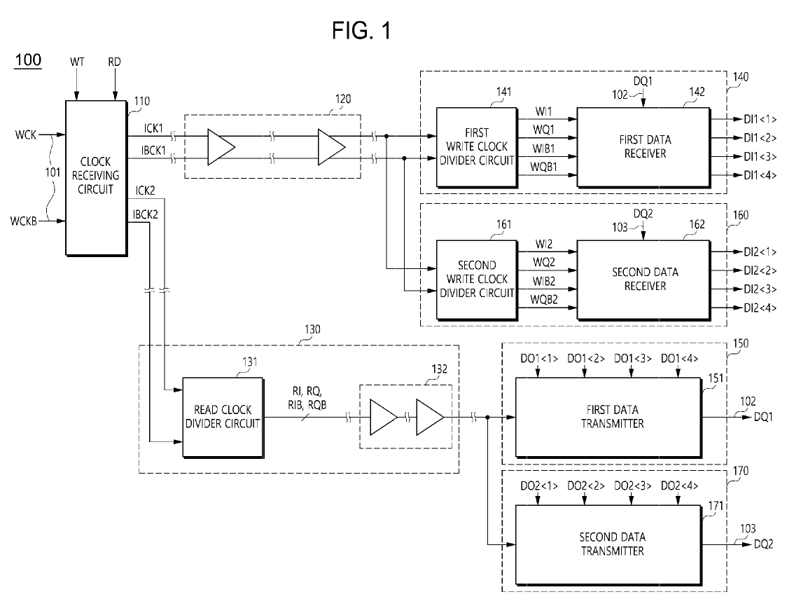

FIG. 1 is a diagram illustrating a configuration of a semiconductor apparatus 100 and a clock distribution network according to an embodiment of the present disclosure. The semiconductor apparatus 100 is coupled to an external device and may receive a first data clock signal WCK and a second data clock signal WCKB from the external device. The second data clock signal WCKB may be a complementary clock signal being an inverted signal to the first data clock signal WCK. The semiconductor apparatus 100 may be coupled to the external device through a clock bus 101, and receive the first and second data clock signals WCK, WCKB from the external device through the clock bus 101. The semiconductor apparatus 100 may receive the first and second data clock signals WCK, WCKB to generate a first internal clock signal pair ICK1, IBCK1 and a second internal clock signal pair ICK2, IBCK2. The first internal clock signal pair ICK1, IBCK1 may include a first internal clock signal ICK1 and a first complementary internal clock signal IBCK1. The first complementary internal clock signal IBCK1 may be a complementary signal of the first internal clock signal ICK1. The second internal clock signal pair ICK2, IBCK2 may include a second internal clock signal ICK2 and a second complementary internal clock signal IBCK2. The second complementary internal clock signal IBCK2 may be a complementary signal of the second internal clock signal ICK2.

The semiconductor apparatus 100 may include a clock distribution network for distributing the first internal clock signal pair ICK1, IBCK1 and the second internal clock signal pair ICK2, IBCK2 to internal circuits of the semiconductor apparatus 100. The semiconductor apparatus 100 may perform a write operation and a read operation. The write operation may refer to an operation in which the semiconductor apparatus 100 receives data transmitted from the external device, and the read operation may refer to an operation in which the semiconductor apparatus 100 outputs data to the external device. The semiconductor apparatus 100 may divide the frequency of the first internal clock signal pair ICK1, IBCK1 to generate a plurality of write clock signals, and may divide the frequency of the second internal clock signal pair ICK2, IBCK2 to generate a plurality of read clock signals, in order to increase the timing margins of the write and read operations. The internal circuits may include a data receiving circuit that performs the write operation and a data output circuit that performs the read operation.

The clock distribution network may include a write clock distribution path and a read clock distribution path. The write clock distribution path may transmit the first internal clock signal pair ICK1, IBCK1 to the data output circuit. The read clock distribution path may transmit the second internal clock signal pair ICK2, IBCK2 to the data receiving circuit. The write clock distribution path and the read clock distribution path may have the longest propagation path inside the semiconductor apparatus 100. Therefore, phase skew may occur between the clock signals propagated through the clock distribution paths due to various factors, such as process variations. On the other hand, the read operation synchronizes internal data of the semiconductor apparatus with an internal clock signal, while the write operation synchronizes data transmitted from the external device with the internal clock signal, so the phase skew between the plurality of write clock signals may be more critical than the phase skew between the plurality of read clock signals. Therefore, the write clock distribution path may have a different configuration from the read clock distribution path. The read clock distribution path may divide the frequency of the second internal clock signal pair ICK2, IBCK2 to generate the plurality of read clock signals and may distribute the read clock signals to the data output circuit by transmitting them through a long propagation path. In contrast, the write clock distribution path may transmit the first internal clock signal pair ICK1, IBCK1 through the longest propagation path without dividing its frequency. After reaching the data receiving circuit, the first internal clock signal pair ICK1, IBCK1 may then be divided into the plurality of write clock signals.

Referring to FIG. 1, the semiconductor apparatus 100 may include a clock receiving circuit 110, a first clock distribution circuit 120, a second clock distribution circuit 130, a first data receiving circuit 140, and a first data output circuit 150. The clock receiving circuit 110 may receive the first and second data clock signals WCK, WCKB from the external device, and generate the first internal clock signal pair ICK1, IBCK1 and the second internal clock signal pair ICK2, IBCK2 from the first and second data clock signals WCK, WCKB. The first internal clock signal ICK1 may have a logic level corresponding to the first data clock signal WCK, and the first complementary internal clock signal IBCK1 may have a logic level corresponding to the second data clock signal WCKB. The second internal clock signal ICK2 may have a logic level corresponding to the first data clock signal WCK, and the second complementary internal clock signal IBCK2 may have a logic level corresponding to the second data clock signal WCKB. The clock receiving circuit 110 may provide the first internal clock signal pair ICK1, IBCK1 to the first clock distribution circuit 120. The clock receiving circuit 110 may provide the second internal clock signal pair ICK2, IBCK2 to the second clock distribution circuit 130.

The clock receiving circuit 110 may further receive a write signal WT and a read signal RD. The external device may provide a write command signal to the semiconductor apparatus 100 so that the semiconductor apparatus 100 can perform a write operation, and the semiconductor apparatus 100 may delay the write command signal to generate the write signal WT. The external device may provide a read command signal to the semiconductor apparatus 100 so that the semiconductor apparatus 100 can perform a read operation, and the semiconductor apparatus 100 may delay the read command signal to generate the read signal RD. As described later, the clock receiving circuit 110 may increase a flat section of the first internal clock signal pair ICK1, IBCK1. The flat section may refer to an interval in which the first internal clock signal ICK1 and the first complementary internal clock signal IBCK1 are fixed at different logic levels.

The first clock distribution circuit 120 may be coupled between the clock receiving circuit 110 and the first data output circuit 140. The first clock distribution circuit 120 may receive the first internal clock signal pair ICK1, IBCK1 from the clock receiving circuit 110 and may transmit the first internal clock signal pair ICK1, IBCK1 to the first data output circuit 140. The first clock distribution circuit 120 may repeat the first internal clock signal ICK1 and the first complementary internal clock signal IBCK1 received from the clock receiving circuit 110 and provide the first internal clock signal ICK1 and the first complementary internal clock signal IBCK1 to the data output circuit 140. The first clock distribution circuit 120 may include a plurality of repeaters that repeat the first internal clock signal pair ICK1, IBCK1. The propagation distance of the first internal clock signal pair ICK1, IBCK1 through the first clock distribution circuit 120 may be longer than the sum of the distance from the clock receiving circuit 110 to input terminals of the first clock distribution circuit 120 and the distance from output terminals of the first clock distribution circuit 120 to the first data output circuit 140, over which the first internal clock signal pair ICK1, IBCK1 propagates.

The second clock distribution circuit 130 may be coupled between the clock receiving circuit 110 and the first data receiving circuit 150. The second clock distribution circuit 130 may receive the second internal clock signal pair ICK2, IBCK2 from the clock receiving circuit 110. The second clock distribution circuit 130 may generate a plurality of read clock signals RI, RQ, RIB, RQB by dividing the frequency of the second internal clock signal pair ICK2, IBCK2. The frequency of each of the plurality of read clock signals RI, RQ, RIB, RQB may be half of the frequency of the second internal clock signal ICK2 or the second complementary internal clock signal IBCK2. The plurality of read clock signals RI, RQ, RIB, RQB may include a first read clock signal RI, a second read clock signal RQ, a third read clock signal RIB, and a fourth read clock signal RQB. The first read clock signal RI may have a phase lead of 90 degrees over the second read clock signal RQ, and the second read clock signal RQ may have a phase lead of 90 degrees over the third read clock signal RIB. The third read clock signal RIB may have a phase lead of 90 degrees over the fourth read clock signal RQB, and the fourth read clock signal RQB may have a phase lead of 90 degrees over the first read clock signal RI. The second clock distribution circuit 130 may repeat the first to fourth read clock signals RI, RQ, RIB, RQB and transmit the first to fourth read clock signals RI, RQ, RIB, RQB to the first data receiving circuit 150. The propagation distance of the first to fourth read clock signals RI, RQ, RIB, RQB through the second clock distribution circuit 130 may be longer than the sum of the distance over which the second internal clock signal pair ICK2, IBCK2 propagates from the clock receiving circuit 110 to input terminals of the second clock distribution circuit 130, and the distance over which the first to fourth read clock signals RI, RQ, RIB, RQB propagate from output terminals of the second clock distribution circuit 130 to the first data receiving circuit 150.

The second clock distribution circuit 130 may include a read clock divider circuit 131 and a plurality of repeaters 132. The read clock divider circuit 131 may generate the plurality of read clock signals RI, RQ, RIB, RQB by dividing the frequency of the second internal clock signal pair ICK2, IBCK2. The read clock divider circuit 131 may generate the first to fourth read clock signals RI, RQ, RIB, RQB, which have a lower frequency than the second internal clock signal ICK2 and the second complementary internal clock signal IBCK2. The plurality of repeaters 132 may repeat the plurality of read clock signals RI, RQ, RIB, RQB. The plurality of repeaters 132 may provide the first to fourth read clock signals RI, RQ, RIB, RQB to the first data output circuit 150.

The first data receiving circuit 140 may receive the first internal clock signal pair ICK1, IBCK1 transmitted through the first clock distribution circuit 120. The first data receiving circuit 140 may generate a first plurality of write clock signals WI1, WQ1, WIB1, WQB1 by dividing the frequency of the first internal clock signal pair ICK1, IBCK1 received from the first clock distribution circuit 120. The first data receiving circuit 140 may receive a first data DQ1 based on the first plurality of write clock signals WI1, WQ1, WIB1, WQB1. The first data receiving circuit 140 may generate a first input data DI1<1:4> by receiving the first data DQ1 in synchronization with the first plurality of write clock signals WI1, WQ1, WIB1, WQB1. The first data DQ1 may be a data signal transmitted through a first data bus 102 connecting the external device and the semiconductor apparatus 100. For example, the first data DQ1 may be a serial data signal including a plurality of bits. The first data receiving circuit 140 may sample the first data DQ1 at each rising edge of the first plurality of write clock signals WI1, WQ1, WIB1, WQB1 or each falling edge of the first plurality of write clock signals WI1, WQ1, WIB1, WQB1, and generate the first input data DI1<1:4> from the sampled data. The first input data DI1<1:4> may be a parallel data signal including a plurality of data signals.

The first data receiving circuit 140 may include a first write clock divider circuit 141 and a first data receiver 142. The first write clock divider circuit 141 may divide the frequency of the first internal clock signal pair ICK1, IBCK1 received from the first clock distribution circuit 120 to generate the first plurality of write clock signals WI1, WQ1, WIB1, WQB1. The frequency of each of the first plurality of write clock signals WI1, WQ1, WIB1, WQB1 may be half of the frequency of the first internal clock signal ICK1 or the first complementary internal clock signal IBCK1. The first plurality of write clock signals WI1, WQ1, WIB1, WQB1 may include a first write clock signal WI1, a second write clock signal WQ1, a third write clock signal WIB1, and a fourth write clock signal WQB1. The first write clock signal WI1 may have a phase lead of 90 degrees over the second write clock signal WQ1, and the second write clock signal WQ1 may have a phase lead of 90 degrees over the third write clock signal WIB1. The third write clock signal WIB1 may have a phase lead of 90 degrees over the fourth write clock signal WQB1, and the fourth write clock signal WQB1 may have a phase lead of 90 degrees over the first write clock signal WI1.

The first write clock divider circuit 141 may provide the first to fourth write clock signals WI1, WQ1, WIB1, WQB1 to the first data receiver 142. The first data receiver 142 may receive the first to fourth write clock signals WI1, WQ1, WIB1, WQB1 and the first data DQ1 and generate the first input data DI1<1:4>. For example, the first input data DI1<1:4> may include a first input data signal DI1<1>, a second input data signal DI1<2>, a third input data signal DI1<3>, and a fourth input data signal DI1<4>. The first input data signal DI1<1> may have a logic level corresponding to a logic level of the first data DQ1 at a rising edge or a falling edge of the first write clock signal WI1. The second input data signal DI1<2> may have a logic level corresponding to a logic level of the first data DQ1 at a rising edge or a falling edge of the second write clock signal WQ1. The third input data signal DI1<3> may have a logic level corresponding to a logic level of the first data DQ1 at a rising or a falling edge of the third write clock signal WIB1. The fourth input data signal DI1<4> may have a logic level corresponding to a logic level of the first data DQ1 at a rising or a falling edge of the fourth write clock signal WQB1. In an embodiment, the number of input data signals included in the first input data DI1<1:4> may be a multiple of four, and the first input data DI1<1:4> may include eight input data signals or sixteen input data signals.

The semiconductor apparatus 100 may further include a second data receiving circuit 160. The second data receiving circuit 160 may have a structure substantially identical to the first data receiving circuit 140 and may be coupled in parallel with the first clock distribution circuit 120 together with the first data receiving circuit 140. The second data receiving circuit 160 may receive the first internal clock signal pair ICK1, IBCK1 transmitted through the first clock distribution circuit 120. The second data receiving circuit 160 may generate a second plurality of write clock signals WI2, WQ2, WIB2, WQB2 by dividing the frequency of the first internal clock signal pair ICK1, IBCK1 received from the first clock distribution circuit 120. The second data receiving circuit 160 may receive a second data DQ2 based on the second plurality of write clock signals WI2, WQ2, WIB2, WQB2. The second data receiving circuit 160 may receive the second data DQ2 in synchronization with the second plurality of write clock signals WI2, WQ2, WIB2, WQB2 to generate a second input data DI2<1:4>. The second data DQ2 may be a data signal transmitted through a second data bus 103 connecting the external device and the semiconductor apparatus 100. The second data DQ2 may be a serial data signal as is the first data DQ1. The second data receiving circuit 160 may sample the second data DQ2 at each rising edge or each falling edge of the second plurality of write clock signals WI2, WQ2, WIB2, WQB2, and may generate the second input data DI2<1:4> from the sampled data. The second input data DI2<1:4> may be a parallel data signal.

The second data receiving circuit 160 may include a second write clock divider circuit 161 and a second data receiver 162. The second write clock divider circuit 161 may divide the frequency of the first internal clock signal pair ICK1, IBCK1 received from the first clock distribution circuit 120 to generate the second plurality of write clock signals WI2, WQ2, WIB2, WQB2. The frequency of each of the second plurality of write clock signals WI2, WQ2, WIB2, WQB2 may be half of the frequency of the first internal clock signal ICK1 or the first complementary internal clock signal IBCK1. The second plurality of write clock signals WI2, WQ2, WIB2, WQB2 may have substantially the same phase as the first plurality of write clock signals WI1, WQ1, WIB1, WQB1. The second plurality of write clock signals WI2, WQ2, WIB2, WQB2 may include a first write clock signal WI2, a second write clock signal WQ2, a third write clock signal WIB2, and a fourth write clock signal WQB2. The first write clock signal WI2 may have a phase lead of 90 degrees over the second write clock signal WQ2, and the second write clock signal WQ2 may have a phase lead of 90 degrees over the third write clock signal WIB2. The third write clock signal WIB2 may have a phase lead of 90 degrees over the fourth write clock signal WQB2, and the fourth write clock signal WQB2 may have a phase lead of 90 degrees over the first write clock signal WI2.

The second write clock divider circuit 161 may provide the first to fourth write clock signals WI2, WQ2, WIB2, WQB2 to the second data receiver 162. The second data receiver 162 may receive the first to fourth write clock signals WI2, WQ2, WIB2, WQB2 and the second data DQ2 and generate the second input data DI2<1:4>. For example, the second input data DI2<1:4> may include a first input data signal DI2<1>, a second input data signal DI2<2>, a third input data signal DI2<3>, and a fourth input data signal DI2<4>. The first input data signal DI2<1> may have a logic level corresponding to a logic level of the second data DQ2 at a rising edge or a falling edge of the first write clock signal WI2. The second input data signal DI2<2> may have a logic level corresponding to a logic level of the second data DQ2 at a rising or a falling edge of the second write clock signal WQ2. The third input data signal DI2<3> may have a logic level corresponding to a logic level of the second data DQ2 at a rising or a falling edge of the third write clock signal WIB2. The fourth input data signal DI2<4> may have a logic level corresponding to a logic level of the second data DQ2 at a rising or a falling edge of the fourth write clock signal WQB2. In an embodiment, the number of input data signals included in the second input data DI2<1:4> may be a multiple of four, and the second input data DI2<1:4> may include eight input data signals or sixteen input data signals.

The first data output circuit 150 may receive the plurality of read clock signals RI, RQ, RIB, RQB from the second clock distribution circuit 130. The first data output circuit 150 may output the first output data DO1<1:4> as the first data DQ1 based on the plurality of read clock signals RI, RQ, RIB, RQB. The first data output circuit 150 may transmit the first data DQ1 to the external device through the first data bus 102. The first data output circuit 150 may include a first data transmitter 151. The first data transmitter 151 may output the first data DQ1 by synchronizing the first output data DO1<1:4> to the plurality of read clock signals RI, RQ, RIB, RQB. For example, the first output data DO1<1:4> may include a first output data signal DO1<1>, a second output data signal DO1<2>, a third output data signal DO1<3>, and a fourth output data signal DO1<4>. The first data transmitter 151 may change a logic level of the first data DQ1 according to logic levels of the first to fourth output data signals DO<1:4> at each rising edge or falling edge of the first to fourth read clock signals RI, RQ, RIB, RQB. For example, the first data transmitter 151 may change a logic level of the first data DQ1 according to a logic level of the first output data signal DO1<1> at a rising edge of the first read clock signal RI. The first data transmitter 151 may change a logic level of the first data DQ1 according to a logic level of the second output data signal DO1<2> at a rising edge of the second read clock signal RQ. The first data transmitter 151 may change a logic level of the first data DQ1 according to a logic level of the third output data signal DO1<3> at a rising edge of the third read clock signal RIB. The first data transmitter 151 may change a logic level of the first data DQ1 according to a logic level of the fourth output data signal DO1<4> at a rising edge of the fourth read clock signal RQB.

The semiconductor apparatus 100 may further include a second data output circuit 170. The second data output circuit 170 may have a structure substantially identical to the first data output circuit 150 and may be coupled in parallel with the second clock distribution circuit 130 together with the first data output circuit 150. The second data output circuit 170 may receive the plurality of read clock signals RI, RQ, RIB, RQB from the second clock distribution circuit 130. The second data output circuit 170 may output the second output data DO2<1:4> as the second data DQ2 based on the plurality of read clock signals RI, RQ, RIB, RQB. The second data output circuit 170 may transmit the second data DQ2 to the external device through the second data bus 103. The second data output circuit 170 may include a second data transmitter 171. The second data transmitter 171 may output the second data DQ2 by synchronizing the second output data DO2<1:4> to the plurality of read clock signals RI, RQ, RIB, RQB. For example, the second output data DO2<1:4> may include a first output data signal DO2<1>, a second output data signal DO2<2>, a third output data signal DO2<3>, and a fourth output data signal DO2<4>. The second data transmitter 171 may change a logic level of the second data DQ2 according to logic levels of the first to fourth output data signals DO2<1:4> at each rising edge or falling edge of the first to fourth read clock signals RI, RQ, RIB, RQB. For example, the second data transmitter 171 may change a logic level of the second data DQ2 according to a logic level of the first output data signal DO2<1> at a rising edge of the first read clock signal RI. The second data transmitter 171 may change a logic level of the second data DQ2 according to a logic level of the second output data signal DO2<2> at a rising edge of the second read clock signal RQ. The second data transmitter 171 may change a logic level of the second data DQ2 according to a logic level of the third output data signal DO2<3> at a rising edge of the third read clock signal RIB. The second data transmitter 171 may change a logic level of the second data DQ2 according to a logic level of the fourth output data signal DO2<4> at a rising edge of the fourth read clock signal RQB.

As the bandwidth of the semiconductor apparatus 100 increases, the number of data buses connecting the semiconductor apparatus 100 and the external device may increase, and the semiconductor apparatus 100 should be provided with a number of data receiving circuits and data output circuits corresponding to the number of data buses. Therefore, in order to distribute divided clock signals such as the plurality of write clock signals and the read clock signals from the clock distribution circuit to each data receiving circuit and each data output circuit, a large number of signal transmission lines may be required. In the past, if a phase skew occurred between the divided clock signals due to process variations, the phase skew was corrected by changing the delay of the signal transmission lines. However, it can be difficult to individually correct the delay of each signal transmission line in a semiconductor apparatus with a large number of data receiving circuits and data output circuits. In addition, the data output circuit that performs the read operation uses the internal clock signal of the semiconductor apparatus to output the internal data of the semiconductor apparatus, whereas the data receiving circuit that performs the write operation uses the internal clock signal of the semiconductor apparatus to receive data transmitted from the external device, so the phase skew of the write clock signal may be more critical. According to an embodiment of the present disclosure, the semiconductor apparatus 100 may provide a clock distribution network that transmits the first internal clock signal pair ICK1, IBCK1 through the first clock distribution circuit 120 to reduce or minimize a phase skew that may occur in the first clock distribution circuit 120, and adopts a structure in which the write clock signal is individually generated in each data receiving circuit. Accordingly, the phase skew between the first plurality of write clock signals WI1, WQ1, WIB1, WQB1 and the phase skew between the second plurality of write clock signals WI2, WQ2, WIB2, WQB2 may be reduced or minimized.

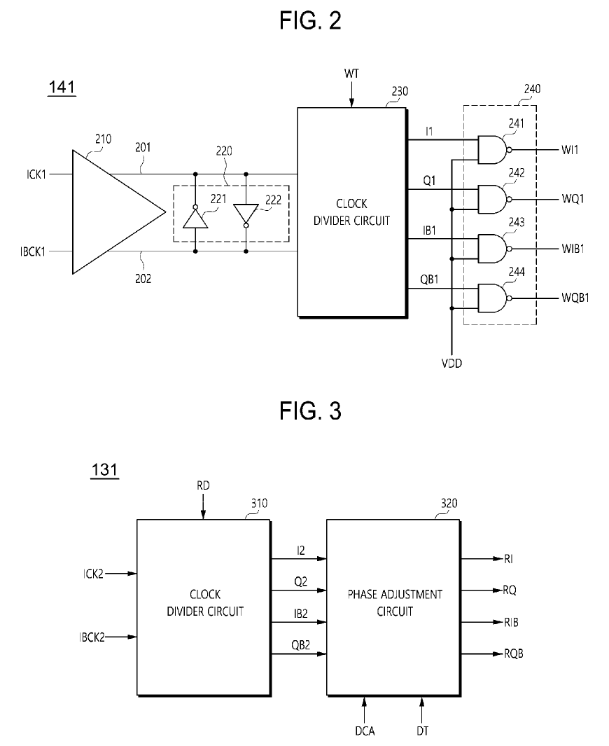

FIG. 2 is a diagram illustrating a configuration of the first write clock divider circuit 141 shown in FIG. 1. Referring to FIG. 2, the first write clock divider circuit 141 may include a buffer 210, a phase averaging circuit 220, a clock divider circuit 230, and an output driver circuit 240. The buffer 210 may receive the first internal clock signal pair ICK1, IBCK1 from the first clock distribution circuit 120. The buffer 210 may buffer the first internal clock signal ICK1 and the first complementary internal clock signal IBCK1. In an embodiment, the buffer 210 may be omitted from components of the first write clock divider circuit 141. The phase averaging circuit 220 may be coupled between the buffer 210 and the clock divider circuit 230. The phase averaging circuit 220 may reduce the phase skew between the first internal clock signal ICK1 and the first complementary internal clock signal IBCK1. For example, the phase averaging circuit 220 may change the phase difference between the first internal clock signal ICK1 and the first complementary internal clock signal IBCK1 to be close to 180 degrees.

The phase averaging circuit 220 may include a first inverter 221 and a second inverter 222. An input terminal of the first inverter 221 may be coupled to a line 202 to which the first complementary internal clock signal IBCK1 is transmitted, and an output terminal of the first inverter 221 may be coupled to a line 201 to which the first internal clock signal ICK1 is transmitted. The first inverter 221 may invert and drive the first complementary internal clock signal IBCK1 to change a voltage level of the first internal clock signal ICK1. An input terminal of the second inverter 222 may be coupled to a line 201 to which the first internal clock signal ICK1 is transmitted, and an output terminal of the second inverter 222 may be coupled to a line 202 to which the first complementary internal clock signal IBCK1 is transmitted. The second inverter 222 may invert and drive the first internal clock signal ICK1 to change a voltage level of the first complementary internal clock signal IBCK1.

The clock divider circuit 230 may receive the first internal clock signal ICK1 through the line 201 and the first complementary internal clock signal IBCK1 through the line 202. The clock divider circuit 230 may divide the frequency of the first internal clock signal ICK1 and the first complementary internal clock signal IBCK1 to generate a first divided clock signal I1, a second divided clock signal Q1, a third divided clock signal IB1, and a fourth divided clock signal QB1. The clock divider circuit 230 may further receive the write signal WT and may be activated based on the write signal WT.

The output driver circuit 240 may receive the first to fourth divided clock signals I1, Q1, IB1, QB1 and drive the first to fourth divided clock signals I1, Q1, IB1, QB1 to output the first to fourth write clock signals WI1, WQ1, WIB1, WQB1. The output driver circuit 240 may include a first NAND gate 241, a second NAND gate 242, a third NAND gate 243, and a fourth NAND gate 244. The first to fourth NAND gates 241, 242, 243, 244 may operate as an inverter by receiving a power supply voltage VDD in common. The first NAND gate 241 may invert and drive the first divided clock signal I1 to output the first write clock signal WI1. The second NAND gate 242 may invert and drive the second divided clock signal Q1 to output the second write clock signal WQ1. The third NAND gate 243 may invert and drive the third divided clock signal IB1 to output the third write clock signal WIB1. The fourth NAND gate 244 may invert and drive the fourth divided clock signal QB1 to output the fourth write clock signal WQB1. In an embodiment, the NAND gates that make up the output driver circuit 240 may be replaced with inverters or non-inverting drivers. The second write clock divider circuit 161 shown in FIG. 1 may have a structure substantially identical to the first write clock divider circuit 141 shown in FIG. 2, except for the signals output therefrom.

FIG. 3 is a diagram illustrating a configuration of the read clock divider circuit 131 shown in FIG. 1. Referring to FIG. 3, the read clock divider circuit 131 may include a clock divider circuit 310 and a phase adjustment circuit 320. The clock divider circuit 310 may receive the second internal clock signal ICK2 and the second complementary internal clock signal IBCK2, and divide the frequency of the second internal clock signal ICK2 and the second complementary internal clock signal IBCK2 to generate a first divided clock signal I2, a second divided clock signal Q2, a third divided clock signal IB2, and a fourth divided clock signal QB2. The clock divider circuit 310 may have a configuration substantially identical to the clock divider circuit 230 shown in FIG. 2, except for some control signals. The clock divider circuit 310 may receive the read signal RD and may be activated based on the read signal RD, unlike the clock divider circuit 230 shown in FIG. 2. The semiconductor apparatus 100 may define a write latency and a read latency, and may perform the write operation and the read operation respectively in accordance with the write latency and the read latency. The write latency may be defined as a time from when the semiconductor apparatus 100 receives the write command signal from the external device to when it receives data transmitted from the external device. The read latency may be defined as a time from when the semiconductor apparatus 100 receives the read command signal from the external device to when it transmits data to the external device. Typically, the write latency may be shorter than the read latency. Accordingly, separating a signal for activating the clock divider circuit 230 used in the write operation from a signal for activating the clock divider circuit 310 used in the read operation may optimize the power consumption of the semiconductor apparatus 100.

The phase adjustment circuit 320 may receive the first to fourth divided clock signals I2, Q2, IB2, and QB2 from the clock divider circuit 310. The phase adjustment circuit 320 may receive a duty control signal DCA and a delay control signal DT. The phase adjustment circuit 320 may generate the first to fourth read clock signals RI, RQ, RIB, RQB by adjusting the phase of the first to fourth divided clock signals I2, Q2, IB2, QB2 based on at least one of the duty control signal DCA and the delay control signal DT. The phase adjustment circuit 320 may vary the delay amount of the first to fourth divided clock signals I2, Q2, IB2, and QB2 based on the duty control signal DCA and the delay control signal DT. The duty control signal DCA may have a dynamically changing value. The semiconductor apparatus 100 may detect the phase skew between the first to fourth read clock signals RI, RQ, RIB, RQB and change the value of the duty control signal DCA to adjust the phase skew of the first to fourth read clock signals RI, RQ, RIB, RQB. In an embodiment, the external device may detect the phase skew of the first to fourth read clock signals RI, RQ, RIB, RQB based on data or a data strobe signal transmitted from the semiconductor apparatus 100 and may provide a command signal to the semiconductor apparatus 100 to change the value of the duty control signal DCA. The semiconductor apparatus 100 may change the value of the duty control signal DCA based on the command signal. The delay control signal DT may have a fixed value. For example, the delay control signal DT may have a fixed value by rupturing a fuse based on results of a wafer or package-level test. The duty control signal DCA and the delay control signal DT may be digital signals having multiple bits or analog signals having various voltage levels.

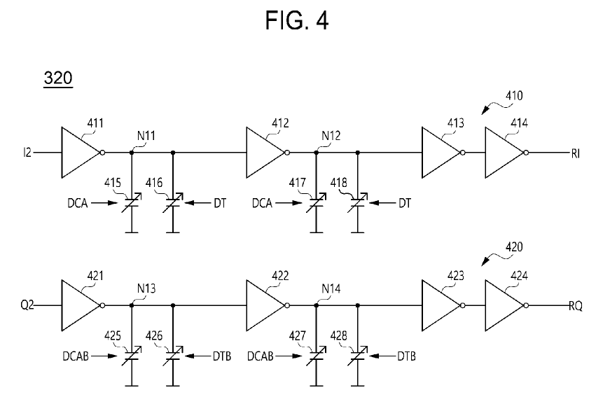

FIG. 4 is a diagram illustrating a configuration of the phase adjustment circuit 320 shown in FIG. 3. As shown in FIG. 4, the phase adjustment circuit 320 may include a first delay circuit 410 and a second delay circuit 420. The first delay circuit 410 may receive the first divided clock signal I2 and delay the first divided clock signal I2 based on the duty control signal DCA and the delay control signal DT to generate the first read clock signal RI. The second delay circuit 420 may receive the second divided clock signal Q2 and generate the second read clock signal RQ by delaying the second divided clock signal Q2 based on a complementary signal DCAB of the duty control signal and a complementary signal DTB of the delay control signal. While a delay amount of the first delay circuit 410 may change based on the duty control signal DCA and the delay control signal DT, a delay amount of the second delay circuit 420 may change based on the complementary signal DCAB of the duty control signal and the complementary signal DTB of the delay control signal. Therefore, the phase adjustment directions of the first and second read clock signals RI, RQ may be opposite to each other. Although not illustrated, the phase adjustment circuit 320 may further include a third delay circuit that delays the third divided clock signal IB2 to generate the third read clock signal RIB, and a fourth delay circuit that delays the fourth divided clock signal QB2 to generate the fourth read clock signal RQB. A delay amount of the third delay circuit may change based on the duty control signal DCA and the delay control signal DT, as in the first delay circuit 410, and a delay amount of the fourth delay circuit may change based on the complementary signal DCAB of the duty control signal and the complementary signal DTB of the delay control signal, as in the second delay circuit 420.

The first delay circuit 410 may include an even number of inverters and at least two variable capacitors coupled between the inverters. For example, the first delay circuit 410 may include a first inverter 411, a second inverter 412, a third inverter 413, a fourth inverter 414, a first variable capacitor 415, a second variable capacitor 416, a third variable capacitor 417, and a fourth variable capacitor 418. An input terminal of the first inverter 411 may receive the first divided clock signal I2, and an output terminal of the first inverter 411 may be coupled to a first node N11. An input terminal of the second inverter 412 may be coupled to the first node N11, and an output terminal of the second inverter 412 may be coupled to a second node N12. An input terminal of the third inverter 413 may be coupled to the second node N12. An input terminal of the fourth inverter 414 may be coupled to an output terminal of the third inverter 413, and the first read clock signal RI may be output from an output terminal of the fourth inverter 414. The first and second variable capacitors 415, 416 may be coupled in parallel to the first node N11. The first variable capacitor 415 may have a capacitance that varies based on the duty control signal DCA, and the second variable capacitor 416 may have a capacitance that varies based on the delay control signal DT. The third and fourth variable capacitors 417, 418 may be coupled in parallel to the second node N12. The third variable capacitor 417 may have a capacitance that varies based on the duty control signal DCA, and the fourth variable capacitor 418 may have a capacitance that varies based on the delay control signal DT. As the capacitance values of the first to fourth variable capacitors 415, 416, 417, 418 increase based on the duty control signal DCA and the delay control signal DT, a delay amount of the first delay circuit 410 may increase and a phase of the first read clock signal RI may be delayed. Conversely, as the capacitance values of the first to fourth variable capacitors 415, 416, 417, 418 decrease based on the duty control signal DCA and the delay control signal DT, a delay amount of the first delay circuit 410 may decrease and a phase of the first read clock signal RI may be advanced.

Similar to the first delay circuit 410, the second delay circuit 420 may include an even number of inverters and at least two variable capacitors coupled between the inverters. For example, the second delay circuit 420 may include a fifth inverter 421, a sixth inverter 422, a seventh inverter 423, an eighth inverter 424, a fifth variable capacitor 425, a sixth variable capacitor 426, a seventh variable capacitor 427, and an eighth variable capacitor 428. An input terminal of the fifth inverter 421 may receive the second divided clock signal Q2, and an output terminal of the fifth inverter 421 may be coupled to a third node N13. An input terminal of the sixth inverter 422 may be coupled to the third node N13, and an output terminal of the sixth inverter 422 may be coupled to a fourth node N14. An input terminal of the seventh inverter 423 may be coupled to the fourth node N14, and an input terminal of the eighth inverter 424 may be coupled to an output terminal of the seventh inverter 423, with the second read clock signal RQ being output from an output terminal of the eighth inverter 424. The fifth and sixth variable capacitors 425, 426 may be coupled in parallel to the third node N13. The fifth variable capacitor 425 may have a capacitance that varies based on the complementary signal DCAB of the duty control signal, and the sixth variable capacitor 426 may have a capacitance that varies based on the complementary signal DTB of the delay control signal. The seventh and eighth variable capacitors 427, 428 may be coupled in parallel to the fourth node N14. The seventh variable capacitor 427 may have a capacitance that varies based on the complementary signal DCAB, and the eighth variable capacitor 428 may have a capacitance that varies based on the complementary signal DTB of the delay control signal.

When the phases of the first and third read clock signals RI, RIB are relatively delayed, and the phases of the second and fourth read clock signals RQ, RQB are relatively advanced, the value of the duty control signal DCA may be increased to adjust the phase skew among the first to fourth read clock signals RI, RQ, RIB, RQB. When the value of the duty control signal DCA is increased, the capacitances of the first and third variable capacitors 415, 417, which receive the duty control signal DCA, may be decreased, and the capacitances of the fifth and seventh variable capacitors 425, 427, which receive the complementary signal DCAB of the duty control signal, may be increased. Accordingly, the phases of the first and third read clock signals RI, RIB may be advanced, and the phases of the second and fourth read clock signals RQ, RQB may be delayed. Conversely, when the phases of the first and third read clock signals RI, RIB are relatively advanced, and the phases of the second and fourth read clock signals RQ, RQB are relatively delayed, the value of the duty control signal DCA may be decreased to adjust the phase skew among the first to fourth read clock signals RI, RQ, RIB, RQB. When the value of the duty control signal DCA is decreased, the capacitances of the first and third variable capacitors 415, 417 may be increased, and the capacitances of the fifth and seventh variable capacitors 425, 427 may be decreased. Accordingly, the phases of the first and third read clock signals RI, RIB may be delayed, and the phases of the second and fourth read clock signals RQ, RQB may be advanced.

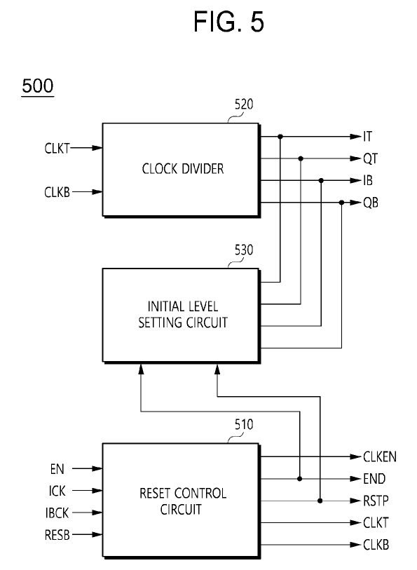

FIG. 5 is a diagram illustrating a configuration of a clock divider circuit 500 according to an embodiment of the present disclosure. The clock divider circuit 500 may be applied to the clock divider circuits 230 and 310 illustrated in FIGS. 2 and 3, respectively. The clock divider circuit 500 may receive an enable signal EN, a first input clock signal ICK, and a second input clock signal IBCK to generate first to fourth divided clock signals IT, QT, IB, QB. When the clock divider circuit 500 is applied as the clock divider circuit 230 illustrated in FIG. 2, the enable signal EN may correspond to the write signal WT. The first and second input clock signals ICK, IBCK may correspond to the first internal clock signal ICK1 and the first complementary internal clock signal IBCK1, respectively. The first to fourth divided clock signals IT, QT, IB, QB may correspond to the first to fourth divided clock signals I1, Q1, IB1, QB1, respectively. When the clock divider circuit 500 is applied as the clock divider circuit 410 illustrated in FIG. 3, the enable signal EN may correspond to the read signal RD. The first and second input clock signals ICK, IBCK may correspond to the second internal clock signal ICK2 and the second complementary internal clock signal IBCK2, respectively. The first to fourth divided clock signals IT, QT, IB, QB may correspond to the first to fourth divided clock signals I2, Q2, IB2, QB2, respectively.

Referring to FIG. 5, the clock divider circuit 500 may include a reset control circuit 510, a clock divider 520, and an initial level setting circuit 530. The reset control circuit 510 may receive the enable signal EN, the first input clock signal ICK, and the second input clock signal IBCK to generate a first gating clock signal CLKT, a second gating clock signal CLKB, and a divider enable signal CLKEN. The reset control circuit 510 may generate the divider enable signal CLKEN based on the enable signal EN and the second input clock signal IBCK. The reset control circuit 510 may enable the divider enable signal CLKEN when the enable signal EN is enabled and the first and second input clock signals ICK, IBCK have different logic levels. The reset control circuit 510 may determine that the first and second input clock signals ICK, IBCK have different logic levels by detecting a transition of a logic level of the second input clock signal IBCK from a high logic level to a low logic level. The reset control circuit 510 may output the first and second gating clock signals CLKT, CLKB by buffering the first and second input clock signals ICK, IBCK after the divider enable signal CLKEN is enabled. The reset control circuit 510 may generate the first gating clock signal CLKT by buffering the first input clock signal ICK, and may generate the second gating clock signal CLKB by buffering the second input clock signal IBCK. The reset control circuit 510 may further generate an initial setting signal END and a reset pulse signal RSTP based on the divider enable signal CLKEN. The initial setting signal END may be a signal enabled after a slight delay following the enabling of the divider enable signal CLKEN. The reset pulse signal RSTP may be enabled to have a predetermined pulse width at the time when the initial setting signal END is enabled. The word “predetermined” as used herein with respect to a parameter, such as a predetermined timing, time, or voltage level, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm. The reset control circuit 510 may output the first and second gating clock signals CLKT, CLKB from the first and second input clock signals ICK, IBCK when the initial setting signal END is enabled. The reset control circuit 510 may provide the first and second gating clock signals CLKT, CLKB to the clock divider 520, and may provide the initial setting signal END and the reset pulse signal RSTP to the initial level setting circuit 530.

The clock divider 520 may receive the first and second gating clock signals CLKT, CLKB from the reset control circuit 510. The clock divider 520 may generate the first to fourth divided clock signals IT, QT, IB, QB based on the first and second gating clock signals CLKT, CLKB. The clock divider 520 may generate the first to fourth divided clock signals IT, QT, IB, QB having a lower frequency than the first and second gating clock signals CLKT, CLKB, based on the first and second gating clock signals CLKT, CLKB. For example, the clock divider 520 may generate the first to fourth divided clock signals IT, QT, IB, QB, each having half of the frequency of the first gating clock signal CLKT or the second gating clock signal CLKB. The configuration and operation of the clock divider 520 are described in detail below.

The initial level setting circuit 530 may set initial logic levels of the first to fourth divided clock signals IT, QT, IB, QB based on the initial setting signal END and the reset pulse signal RSTP, which, in turn, are based on the divider enable signal CLKEN. The initial level setting circuit 530 may receive the initial setting signal END and the reset pulse signal RSTP from the reset control circuit 510. The initial level setting circuit 530 may set the initial logic levels of the first to fourth divided clock signals IT, QT, IB, QB in response to the initial setting signal END and the reset pulse signal RSTP. When the initial setting signal END is disabled, the initial level setting circuit 530 may maintain the logic levels of the first to fourth divided clock signals IT, QT, IB, QB at the same level. When the initial setting signal END is enabled, the initial level setting circuit 530 may set the first and third divided clock signals IT, IB to different logic levels and set the second and fourth divided clock signals QT, QB to different logic levels. The initial level setting circuit 530 may set the logic levels of the first and second divided clock signals IT, QT to the same level and set the logic levels of the third and fourth divided clock signals IB, QB to the same level.

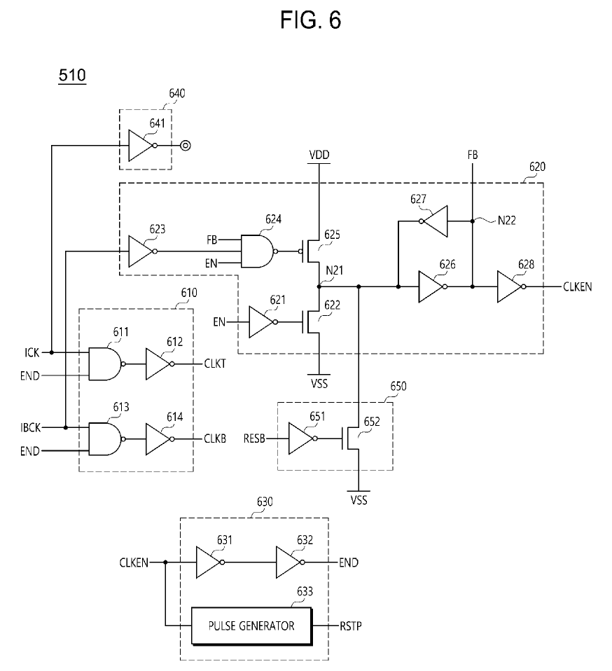

FIG. 6 is a diagram illustrating a configuration of the reset control circuit 510 shown in FIG. 5. Referring to FIG. 6, the reset control circuit 510 may include a clock gating circuit 610, an enable signal generation circuit 620, and a control signal generation circuit 630. The clock gating circuit 610 may receive the first input clock signal ICK, the second input clock signal IBCK, and the initial setting signal END. When the initial setting signal END is disabled, the clock gating circuit 610 may block the first and second input clock signals ICK, IBCK from being output as the first and second gating clock signals CLKT, CLKB, and may fix the logic levels of the first and second gating clock signals CLKT, CLKB to a low logic level. When the initial setting signal END is enabled, the clock gating circuit 610 may output the first and second input clock signals ICK, IBCK as the first and second gating clock signals CLKT, CLKB, respectively. The logic levels of the first and second gating clock signals CLKT, CLKB may change according to the logic levels of the first and second input clock signals ICK, IBCK, respectively.

The enable signal generation circuit 620 may receive the enable signal EN and the second input clock signal IBCK, and may generate the divider enable signal CLKEN based on the enable signal EN and the second input clock signal IBCK. When the enable signal EN is disabled, the enable signal generation circuit 620 may maintain the divider enable signal CLKEN at a low logic level. When the enable signal EN is enabled at a high logic level, the enable signal generation circuit 620 may enable the divider enable signal CLKEN according to a logic level of the second input clock signal IBCK. The enable signal generation circuit 620 may enable the divider enable signal CLKEN when the enable signal EN is enabled and the second input clock signal IBCK transitions from a high logic level to a low logic level. The enable signal generation circuit 620 may maintain the enabled state of the divider enable signal CLKEN until the enable signal EN is disabled.

The control signal generation circuit 630 may receive the divider enable signal CLKEN and may generate the initial setting signal END and the reset pulse signal RSTP based on the divider enable signal CLKEN. The control signal generation circuit 630 may generate the initial setting signal END by delaying the divider enable signal CLKEN. The control signal generation circuit 630 may delay the divider enable signal CLKEN, and generate the reset pulse signal RSTP having a predetermined pulse width based on the initial setting signal END and the delayed divider enable signal. The initial setting signal END may be a level signal that is enabled from a low logic level to a high logic level and maintained at a high logic level. The reset pulse signal RSTP may be enabled simultaneously with a time point at which the initial setting signal END is enabled, and may be enabled at a high logic level for a duration corresponding to the predetermined pulse width.

The reset control circuit 510 may further include a dummy circuit 640 and a reset circuit 650. The dummy circuit 640 may receive the first input clock signal ICK. Because the enable signal generation circuit 620 generates the divider enable signal CLKEN by detecting a logic level transition of the second input clock signal IBCK, the load of the line through which the second input clock signal IBCK is transmitted may be greater than the load of the line through which the first input clock signal ICK is transmitted. A capacitive load difference, for example, between the lines transmitting the first and second input clock signals ICK, IBCK may cause a phase skew between the first and second input clock signals ICK, IBCK. The dummy circuit 640 may be provided to match the load of the line transmitting the first input clock signal ICK to the load of the line transmitting the second input clock signal IBCK. The reset circuit 650 may receive a reset signal RESB and may disable the divider enable signal CLKEN based on the reset signal RESB. The reset signal RESB may be enabled when the semiconductor apparatus 100 is initialized or powered up. The reset circuit 650 may disable the divider enable signal CLKEN regardless of other signals when the reset signal RESB is enabled.

The clock gating circuit 610 may include a first NAND gate 611, a first inverter 612, a second NAND gate 613, and a second inverter 614. The first NAND gate 611 may receive the first input clock signal ICK and the initial setting signal END. The first inverter 612 may invert an output signal of the first NAND gate 611 to output the first gating clock signal CLKT. The second NAND gate 613 may receive the second input clock signal IBCK and the initial setting signal END. The second inverter 614 may invert an output signal of the second NAND gate 613 to output the second gating clock signal CLKB.

The enable signal generation circuit 620 may include a first inverter 621, a first transistor 622, a second inverter 623, a NAND gate 624, a second transistor 625, a third inverter 626, a fourth inverter 627, and a fifth inverter 628. The first inverter 621 may receive the enable signal EN and invert the enable signal EN. The first transistor 622 may be an NMOS transistor. A gate of the first transistor 622 may receive an output signal of the first inverter 621, a drain of the first transistor 622 may be coupled to a first node N21, and a source of the first transistor 622 may be coupled to a ground voltage VSS. The second inverter 623 may receive the second input clock signal IBCK and invert the second input clock signal IBCK. The NAND gate 624 may receive the enable signal EN, an output signal of the second inverter 623, and a feedback signal FB. The second transistor 625 may be a PMOS transistor. A gate of the second transistor 625 may receive an output signal of the NAND gate 624, a source of the second transistor 625 may receive a supply voltage VDD, and a drain of the second transistor 625 may be coupled to the first node N21. An input terminal of the third inverter 626 may be coupled to the first node N21, and an output terminal of the third inverter 626 may be coupled to a second node N22. An input terminal of the fourth inverter 627 may be coupled to the second node N22, and an output terminal of the fourth inverter 627 may be coupled to the first node N21. The third and fourth inverters 626, 627 may form a latch. The feedback signal FB may be output from the second node N22. An input terminal of the fifth inverter 628 may be coupled to the second node N22, and the divider enable signal CLKEN may be output from an output terminal of the fifth inverter 628.

The control signal generation circuit 630 may include a first inverter 631, a second inverter 632, and a pulse generator 633. An input terminal of the first inverter 631 may receive the divider enable signal CLKEN. An input terminal of the second inverter 632 may be coupled to an output terminal of the first inverter 631, and the initial setting signal END may be output from an output terminal of the second inverter 632. The pulse generator 633 may receive the divider enable signal CLKEN and may generate the reset pulse signal RSTP having a pulse that is enabled at the same timing as the initial setting signal END.

The dummy circuit 640 may include a first inverter 641. An input terminal of the first inverter 641 may receive the first input clock signal ICK, and an output terminal of the first inverter 641 may be left floating. The first inverter 641 may have the same current driving capability as the second inverter 623 of the enable signal generation circuit 620. The reset circuit 650 may include a second inverter 651 and a transistor 652. The transistor 652 may be an NMOS transistor. The second inverter 651 may receive the reset signal RESB and invert the reset signal RESB. A gate of the transistor 652 may receive an output signal of the second inverter 651, a drain of the transistor 652 may be coupled to the first node N21, and a source of the transistor 652 may be coupled to the ground voltage VSS.

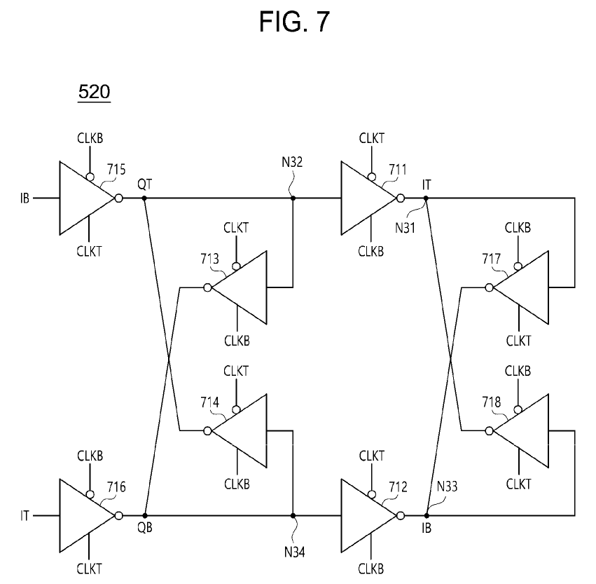

FIG. 7 is a diagram illustrating a configuration of the clock divider 520 shown in FIG. 5. Referring to FIG. 7, the clock divider 520 may generate the first to fourth divided clock signals IT, QT, IB, QB in response to the first and second gating clock signals CLKT, CLKB. When the first gating clock signal CLKT is at a first logic level and the second gating clock signal CLKB is at a second logic level, the clock divider 520 may invert the second divided clock signal QT to output the first divided clock signal IT, invert the fourth divided clock signal QB to output the third divided clock signal IB, invert the second divided clock signal QT to output the fourth divided clock signal QB, and invert the fourth divided clock signal QB to output the second divided clock signal QT. The first logic level may be a low logic level, and the second logic level may be a high logic level. When the first gating clock signal CLKT is at the second logic level and the second gating clock signal CLKB is at the first logic level, the clock divider 520 may invert the first divided clock signal IT to output the fourth divided clock signal QB, invert the third divided clock signal IB to output the second divided clock signal QT, invert the first divided clock signal IT to output the third divided clock signal IB, and invert the third divided clock signal IB to output the first divided clock signal IT.

The clock divider 520 may include a first inverter 711, a second inverter 712, a third inverter 713, a fourth inverter 714, a fifth inverter 715, a sixth inverter 716, a seventh inverter 717, and an eighth inverter 718. The first to eighth inverters 711, 712, 713, 714, 715, 716, 717, 718 may be tri-state inverters that receive the first and second gating clock signals CLKT, CLKB as control signals. When the first gating clock signal CLKT is at a low logic level and the second gating clock signal CLKB is at a high logic level, the first to fourth inverters 711, 712, 713, 714 may be activated. When the first gating clock signal CLKT is at a high logic level and the second gating clock signal CLKB is at a low logic level, the fifth to eighth inverters 715, 716, 717, 718 may be activated. An input terminal of the first inverter 711 may be coupled to a second node N32, and an output terminal of the first inverter 711 may be coupled to a first node N31. An input terminal of the second inverter 712 may be coupled to a fourth node N34, and an output terminal of the second inverter 712 may be coupled to a third node N33. The first divided clock signal IT may be output from the first node N31, and the second divided clock signal QT may be output from the second node N32. The third divided clock signal IB may be output from the third node N33, and the fourth divided clock signal QB may be output from the fourth node N34. An input terminal of the third inverter 713 may be coupled to the second node N32, and an output terminal of the third inverter 713 may be coupled to the fourth node N34. An input terminal of the fourth inverter 714 may be coupled to the fourth node N34, and an output terminal of the fourth inverter 714 may be coupled to the second node N32. An input terminal of the fifth inverter 715 may be coupled to the third node N33, and an output terminal of the fifth inverter 715 may be coupled to the second node N32. An input terminal of the sixth inverter 716 may be coupled to the first node N31, and an output terminal of the sixth inverter 716 may be coupled to the fourth node N34. An input terminal of the seventh inverter 717 may be coupled to the first node N31, and an output terminal of the seventh inverter 717 may be coupled to the third node N33. An input terminal of the eighth inverter 718 may be coupled to the third node N33, and an output terminal of the eighth inverter 718 may be coupled to the first node N31.

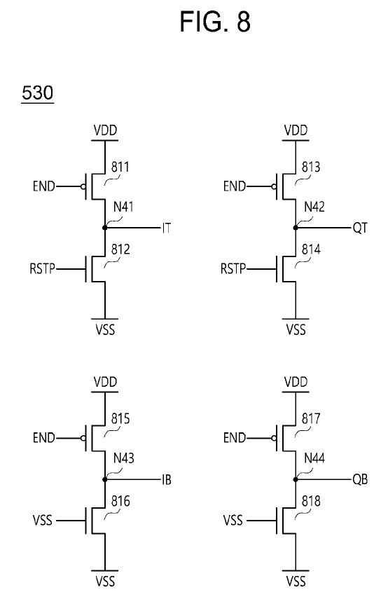

FIG. 8 is a diagram illustrating a configuration of the initial level setting circuit 530 shown in FIG. 5. Referring to FIG. 8, the initial level setting circuit 530 may include a first transistor 811, a second transistor 812, a third transistor 813, a fourth transistor 814, a fifth transistor 815, a sixth transistor 816, a seventh transistor 817, and an eighth transistor 818. The first, third, fifth, and seventh transistors 811, 813, 815, and 817 may be PMOS transistors, and the second, fourth, sixth, and eighth transistors 812, 814, 816, and 818 may be NMOS transistors. A gate of the first transistor 811 may receive the initial setting signal END, a drain of the first transistor 811 may receive the supply voltage VDD, and a source of the first transistor 811 may be coupled to a first node N41. A gate of the second transistor 812 may receive the reset pulse signal RSTP, a drain of the second transistor 812 may be coupled to the first node N41, and a source of the second transistor 812 may be coupled to the ground voltage VSS. The first clock signal IT may be output from the first node N41. The first node N41 may be coupled to the first node N31 of FIG. 7. A gate of the third transistor 813 may receive the initial setting signal END, a drain of the third transistor 813 may receive the supply voltage VDD, and a source of the third transistor 813 may be coupled to a second node N42. A gate of the fourth transistor 814 may receive the reset pulse signal RSTP, a drain of the fourth transistor 814 may be coupled to the second node N42, and a source of the fourth transistor 814 may be coupled to the ground voltage VSS. The second divided clock signal QT may be output from the second node N42. The second node N42 may be coupled to the second node N32 of FIG. 7. A gate of the fifth transistor 815 may receive the initial setting signal END, a drain of the fifth transistor 815 may receive the supply voltage VDD, and a source of the fifth transistor 815 may be coupled to a third node N43. A gate of the sixth transistor 816 may be coupled to the ground voltage VSS, a drain of the sixth transistor 816 may be coupled to the third node N43, and a source of the sixth transistor 816 may be coupled to the ground voltage VSS. The third divided clock signal IB may be output from the third node N43. The third node N43 may be coupled to the third node N33 of FIG. 7. A gate of the seventh transistor 817 may receive the initial setting signal END, a drain of the seventh transistor 817 may receive the supply voltage VDD, and a source of the seventh transistor 817 may be coupled to a fourth node N44. A gate of the eighth transistor 818 may be coupled to the ground voltage VSS, a drain of the eighth transistor 818 may be coupled to the fourth node N44, and a source of the eighth transistor 818 may be coupled to the ground voltage VSS. The fourth divided clock signal QB may be output from the fourth node N44. The fourth node N44 may be coupled to the fourth node N34 of FIG. 7.

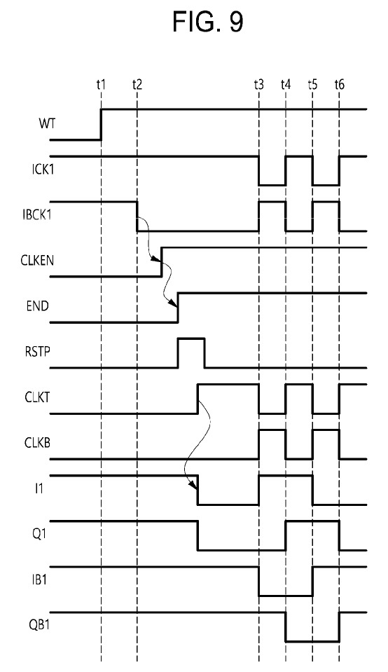

FIG. 9 is a timing diagram illustrating an operation of the clock divider circuit 230 according to an embodiment of the present disclosure. The operation of the clock divider circuit 230 is be described with reference to FIGS. 1, 2, and 5 through 9. When the write signal WT is in a disabled state, the first transistor 622 of the enable signal generation circuit 620 is turned on, and the divider enable signal CLKEN may remain in a disabled state. When the write signal WT is disabled, the first and second data clock signals WCK and WCKB are not input, and the first internal clock signal ICK1 and the first complementary internal clock signal IBCK1 may be maintained at a high logic level. Because the initial setting signal END is also in a disabled state at a low logic level, the first to fourth divided clock signals I1, Q1, IB1, and QB1 may all be maintained at a high logic level. At time t1, although the write signal WT is enabled, the first complementary internal clock signal IBCK1 remains at a high logic level, and thus, the enable signal generation circuit 620 may still maintain the divider enable signal CLKEN in a disabled state.

At time t2, when the first complementary internal clock signal IBCK1 transitions from a high logic level to a low logic level, the second transistor 625 of the enable signal generation circuit 620 is turned on, and after a propagation delay introduced by the inverters 626 and 628 of FIG. 6, the divider enable signal CLKEN may be enabled to a high logic level. After the divider enable signal CLKEN is enabled to a high logic level, the initial setting signal END is enabled after a propagation delay introduced by the inverters 631 and 632 of FIG. 6, and a pulse of the reset pulse signal RSTP may be generated. When the initial setting signal END and the reset pulse signal RSTP are generated, the clock gating circuit 610 may output the first internal clock signal ICK1 and the first complementary internal clock signal IBCK1 as the first and second gating clock signals CLKT and CLKB. The initial level setting circuit 530 may set the initial level of the first and second divided clock signals I1 and Q1 to a low logic level and set the initial level of the third and fourth divided clock signals IB1 and QB1 to a high logic level. At this time, it may be preferable that the pulse width of the reset pulse signal RSTP be set such that the reset pulse signal RSTP is disabled after a rising edge of the first gating clock signal CLKT occurs.

At time t3, the first internal clock signal ICK1 and the first complementary internal clock signal IBCK1 may toggle according to the first and second data clock signals WCK and WCKB. The first gating clock signal CLKT may transition to a low logic level, and the second gating clock signal CLKB may transition to a high logic level. The first to fourth inverters 711, 712, 713, and 714 of the clock divider 520 are activated, the first divided clock signal I1 may be driven to a high logic level, the second divided clock signal Q1 may be driven to a low logic level, the third divided clock signal IB1 may be driven to a low logic level, and the fourth divided clock signal QB1 may be driven to a high logic level. At time t4, when the first gating clock signal CLKT transitions to a high logic level and the second gating clock signal CLKB transitions to a low logic level, the fifth to eighth inverters 715, 716, 717, and 718 of the clock divider 520 may be activated. The first divided clock signal I1 may be driven to a high logic level, the second divided clock signal Q1 may be driven to a high logic level, the third divided clock signal IB1 may be driven to a low logic level, and the fourth divided clock signal QB1 may be driven to a low logic level. At time t5, when the first gating clock signal CLKT transitions again to a low logic level and the second gating clock signal CLKB transitions again to a high logic level, the first to fourth inverters 711, 712, 713, and 714 may be activated. The first divided clock signal I1 may be driven to a low logic level, the second divided clock signal Q1 may be driven to a high logic level, the third divided clock signal IB1 may be driven to a high logic level, and the fourth divided clock signal QB1 may be driven to a low logic level. At time t6, when the first gating clock signal CLKT transitions again to a high logic level and the second gating clock signal CLKB transitions again to a low logic level, the fifth to eighth inverters 715, 716, 717, and 718 may be activated. The first divided clock signal I1 may be driven to a low logic level, the second divided clock signal Q1 may be driven to a low logic level, the third divided clock signal IB1 may be driven to a high logic level, and the fourth divided clock signal QB1 may be driven to a high logic level. Accordingly, the first to fourth divided clock signals I1, Q1, IB1, and QB1 may be generated with a period that is double the period of the first internal clock signal ICK1 and the first complementary internal clock signal IBCK1. In addition, the clock divider circuit 230 may reset or enable the clock divider 520, and set initial levels of the divided clock signals I1, Q1, IB1, and QB1, when the first internal clock signal pair ICK1 and IBCK1 have different logic levels, i.e., during a flat section. Therefore, it is possible to prevent or mitigate a metastable state in which the logic levels of the divided clock signals I1, Q1, IB1, and QB1 cannot be clearly distinguished due to the clock divider 520 being enabled outside the flat section.

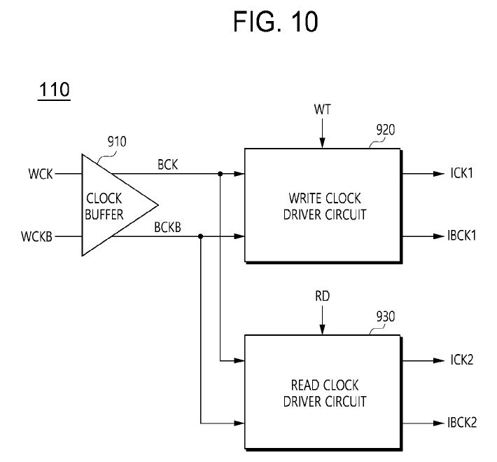

FIG. 10 illustrates a configuration of the clock receiving circuit 110 shown in FIG. 1. The clock receiving circuit 110 may include a clock buffer 910, a write clock driver circuit 920, and a read clock driver circuit 930. The clock buffer 910 may receive the first and second data clock signals WCK and WCKB, buffer the first and second data clock signals WCK and WCKB, and output a first buffered clock signal BCK and a second buffered clock signal BCKB. The clock buffer 910 may differentially amplify the first and second data clock signals WCK and WCKB to generate the first and second buffered clock signals BCK and BCKB. The second buffered clock signal BCKB may be a differential signal having a logic level opposite to the first buffered clock signal BCK. The first buffered clock signal BCK may have a logic level corresponding to the first data clock signal WCK, and the second buffered clock signal BCKB may have a logic level corresponding to the second data clock signal WCKB.

The write clock driver circuit 920 may generate the first internal clock signal pair ICK1 and IBCK1 based on the write signal WT and the first and second buffered clock signals BCK and BCKB. The write clock driver circuit 920 may be activated based on the write signal WT. When the write signal WT is disabled, the write clock driver circuit 920 may fix the logic levels of the first internal clock signal ICK1 and the first complementary internal clock signal IBCK1 to the same logic level. For example, the write clock driver circuit 920 may fix the first internal clock signal ICK1 and the first complementary internal clock signal IBCK1 to a high logic level. When the write signal WT is enabled, the write clock driver circuit 920 may be at least partially activated and may set the logic levels of the first internal clock signal ICK1 and the first complementary internal clock signal IBCK1 to different logic levels. For example, the write clock driver circuit 920 may set a logic level of the first internal clock signal ICK1 to a high logic level and set a logic level of the first complementary internal clock signal IBCK1 to a low logic level.

The write clock driver circuit 920 may be fully activated after the first and second buffered clock signals BCK and BCKB toggle at least once according to the first and second data clock signals WCK and WCKB. Alternatively, the write clock driver circuit 920 may be fully activated after the first and second buffered clock signals BCK and BCKB start toggling and after a time corresponding to at least 1tCK has elapsed. The time corresponding to 1tCK may be a time corresponding to one cycle of the first and second data clock signals WCK and WCKB. In an embodiment, the time corresponding to 1tCK may be a time corresponding to half of the preamble interval of the first and second data clock signals WCK and WCKB. The write clock driver circuit 920 may drive the first and second buffered clock signals BCK and BCKB after they toggle at least once to generate the first internal clock signal ICK1 and the first complementary internal clock signal IBCK1. Accordingly, the write clock driver circuit 920 may set the logic levels of the first internal clock signal pair ICK1 and IBCK1 to opposite logic levels until the write signal WT is enabled and the first and second buffered clock signals BCK and BCKB toggle at least once, and may then change the logic levels of the first internal clock signal pair ICK1 and IBCK1 based on the first and second buffered clock signals BCK and BCKB after they toggle at least once. In an embodiment, the write clock driver circuit 920 may be modified to generate the first internal clock signal pair ICK1 and IBCK1 by driving the first and second buffered clock signals BCK and BCKB after the first and second buffered clock signals BCK and BCKB toggle twice.

The write clock driver circuit 920 may generate the first internal clock signal ICK1 and the first complementary internal clock signal IBCK1 by inverting the first and second buffered clock signals BCK and BCKB. The first internal clock signal ICK1 may have a logic level opposite to the first buffered clock signal BCK, and the first complementary internal clock signal IBCK1 may have a logic level opposite to the second buffered clock signal BCKB. In an embodiment, the write clock driver circuit 920 may be modified to generate the first internal clock signal pair ICK1 and IBCK1 by non-inverting the first and second buffered clock signals BCK and BCKB.

The read clock driver circuit 930 may generate the second internal clock signal pair ICK2 and IBCK2 based on the read signal RD and the first and second buffered clock signals BCK and BCKB. The read clock driver circuit 930 may be activated based on the read signal RD. When the read signal RD is disabled, the read clock driver circuit 930 may fix logic levels of the second internal clock signal ICK2 and the second complementary internal clock signal IBCK2 to the same logic level. For example, the read clock driver circuit 930 may fix the second internal clock signal ICK2 and the second complementary internal clock signal IBCK2 to a high logic level. When the read signal RD is enabled, the read clock driver circuit 930 may be fully activated and may drive the first and second buffered clock signals BCK and BCKB to generate the second internal clock signal ICK2 and the second complementary internal clock signal IBCK2. The read clock driver circuit 930 may generate the second internal clock signal ICK2 and the second complementary internal clock signal IBCK2 by inverting the first and second buffered clock signals BCK and BCKB. The second internal clock signal ICK2 may have a logic level opposite to the first buffered clock signal BCK, and the second complementary internal clock signal IBCK2 may have a logic level opposite to the second buffered clock signal BCKB. In an embodiment, the read clock driver circuit 930 may be modified to generate the second internal clock signal pair ICK2 and IBCK2 by non-inverting the first and second buffered clock signals BCK and BCKB.

The external device may transmit the write command signal or the read command signal to the semiconductor apparatus 100, and then provide the first and second data clock signals WCK and WCKB to the semiconductor apparatus 100. At this time, to indicate the timing of data transfer along with the first and second data clock signals WCK and WCKB, the first and second data clock signals WCK and WCKB may include a preamble. For example, the first and second data clock signals WCK and WCKB may include a 2tCK preamble, and bodies of the first and second data clock signals WCK and WCKB may be transmitted after the 2tCK preamble. Similarly, to indicate that the transmission of the first and second data clock signals WCK and WCKB and data has been completed, the first and second data clock signals WCK and WCKB may include a postamble. For example, the first and second data clock signals WCK and WCKB may include a 1tCK postamble. Because the write latency is shorter than the read latency, when the external device transmits the write command signal to the semiconductor apparatus 100 with a minimal time interval after transmitting the read command signal, there may be cases where the interval between the postamble of the first and second data clock signals WCK and WCKB received for the read operation and the preamble of the first and second data clock signals WCK and WCKB received for the write operation from the external device is very short or gapless. When the interval between the postamble and the preamble is short, a flat section of the first and second data clock signals WCK and WCKB may barely exist, making it difficult to secure sufficient time for the write clock divider circuits 141 and 161 to be reset. Accordingly, the write clock driver circuit 920 may increase a flat section of the first internal clock signal pair ICK1 and IBCK1 based on the write signal WT, thereby ensuring that the write clock divider circuits 141 and 161 have sufficient time to be reset. In contrast, because the read latency is sufficiently long, a flat section of the first and second data clock signals WCK and WCKB may sufficiently exist even when the read operation is performed after the write operation or another read operation. Accordingly, the read clock driver circuit 930 does not need to increase a flat section of the second internal clock signal pair ICK2 and IBCK2, and may have a simple circuit structure and consume low power.

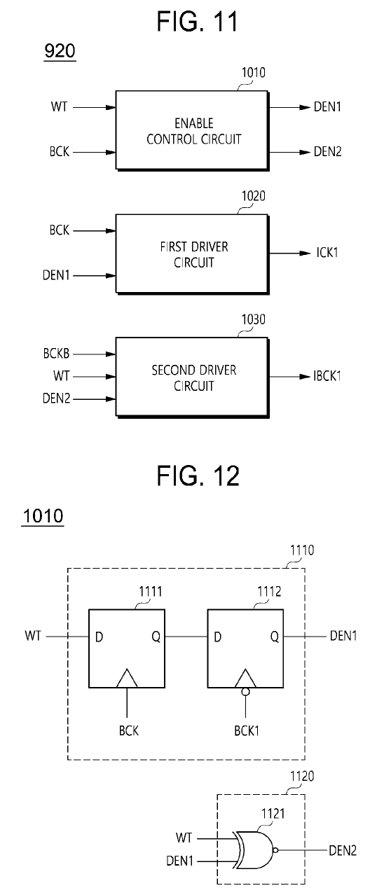

FIG. 11 illustrates a configuration of the write clock driver circuit 920 shown in FIG. 10. Referring to FIG. 11, the write clock driver circuit 920 may include an enable control circuit 1010, a first driver circuit 1020, and a second driver circuit 1030. The enable control circuit 1010 may receive the write signal WT and the first buffered clock signal BCK to generate a first driver enable signal DEN1 and a second driver enable signal DEN2. The second driver enable signal DEN2 may be maintained in an enabled state by default. When the write signal WT is enabled, the enable control circuit 1010 may disable the second driver enable signal DEN2. After the write signal WT is enabled and after the first buffered clock signal BCK has toggled at least once, or after a time corresponding to 1tCK from the time point when the first buffered clock signal BCK starts toggling, the enable control circuit 1010 may enable the first driver enable signal DEN1. When both the write signal WT and the first driver enable signal DEN1 are enabled, the enable control circuit 1010 may enable the second driver enable signal DEN2.

The first driver circuit 1020 may receive the first buffered clock signal BCK and the first driver enable signal DEN1 to generate the first internal clock signal ICK1. The first driver circuit 1020 may fix the first internal clock signal ICK1 to a high logic level when it is deactivated. The first driver circuit 1020 may be activated when the first driver enable signal DEN1 is enabled, and may generate the first internal clock signal ICK1 by inverting the first buffered clock signal BCK. The second driver circuit 1030 may receive the second buffered clock signal BCKB, the write signal WT, and the second driver enable signal DEN2. The second driver circuit 1030 may fix the first complementary internal clock signal IBCK1 to a high logic level when it is deactivated. The second driver circuit 1030 may be partially activated based on the write signal WT. When the second driver circuit 1030 is partially activated, it may set the first complementary internal clock signal IBCK1 to a low logic level. The second driver circuit 1030 may be fully activated when both the write signal WT and the second driver enable signal DEN2 are enabled, and may generate the first complementary internal clock signal IBCK1 by inverting the second buffered clock signal BCKB.

FIG. 12 illustrates a configuration of the enable control circuit 1010 shown in FIG. 11. Referring to FIG. 12, the enable control circuit 1010 may include a first enable control circuit 1110 and a second enable control circuit 1120. The first enable control circuit 1110 may receive the write signal WT and the first buffered clock signal BCK to generate the first driver enable signal DEN1. The first enable control circuit 1110 may count edges of the first buffered clock signal BCK after the write signal WT is enabled, and may enable the first driver enable signal DEN1 after the first buffered clock signal BCK has toggled at least once. The first enable control circuit 1110 may shift the write signal WT in synchronization with edges of the first buffered clock signal BCK to generate the first driver enable signal DEN1. The first enable control circuit 1110 may include a first flip-flop 1111 and a second flip-flop 1112. The first and second flip-flops 1111 and 1112 may be edge-triggered flip-flops. A data input terminal D of the first flip-flop 1111 may receive the write signal WT, and a clock input terminal may receive the first buffered clock signal BCK. A data input terminal D of the second flip-flop 1112 may be coupled to an output terminal Q of the first flip-flop 1111, a clock input terminal may receive an inverted signal of the first buffered clock signal BCK, and the first driver enable signal DEN1 may be output from an output terminal Q of the second flip-flop 1112. The first flip-flop 1111 may output the write signal WT to the second flip-flop 1112 in response to a first edge of the first buffered clock signal BCK (e.g., a rising edge), and the second flip-flop 1112 may output the signal received from the first flip-flop 1111 as the first driver enable signal DEN1 in response to a second edge (e.g., a falling edge).

In an embodiment, the first enable control circuit 1110 may be modified to generate the first driver enable signal DEN1 after the first buffered clock signal BCK has toggled twice. The number of flip-flops included in the first enable control circuit 1110 may be modified to four, where a third flip-flop may operate in response to a third edge of the first buffered clock signal BCK (e.g., a second rising edge of the first buffered clock signal BCK), and a fourth flip-flop may operate in response to a fourth edge of the first buffered clock signal BCK (e.g., a second falling edge of the first buffered clock signal BCK).

The second enable control circuit 1120 may receive the write signal WT and the first driver enable signal DEN1 to generate the second driver enable signal DEN2. The second enable control circuit 1120 may selectively enable the second driver enable signal DEN2 according to logic levels of the write signal WT and the first driver enable signal DEN1. When either the write signal WT or the first driver enable signal DEN1 is disabled, the second enable control circuit 1120 may disable the second driver enable signal DEN2. When both the write signal WT and the first driver enable signal DEN1 are enabled, the second enable control circuit 1120 may enable the second driver enable signal DEN2. The second enable control circuit 1120 may include an exclusive NOR gate 1121. The exclusive NOR gate 1121 may perform an exclusive NOR operation on the write signal WT and the first driver enable signal DEN1, and may output the second driver enable signal DEN2.

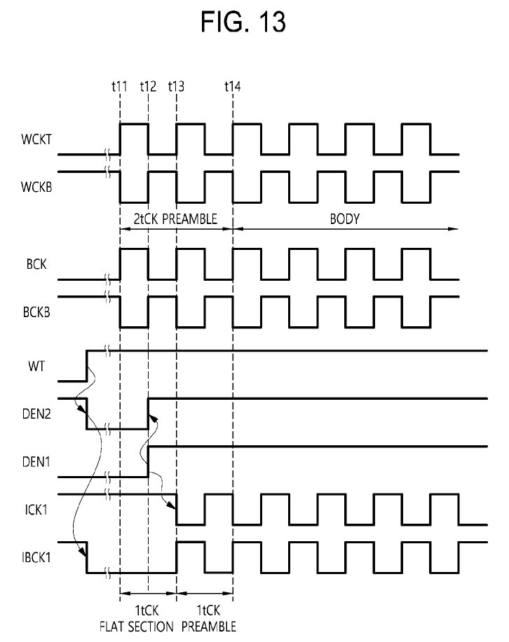

FIG. 13 is a timing diagram illustrating an operation of the clock receiving circuit 110 in an embodiment of the present disclosure. Referring to FIGS. 1 and 10 through 13, the operation of the clock receiving circuit 110 is described as follows. In an initial state, the first and second data clock signals WCK and WCKB are maintained at different logic levels, and the write signal WT may remain in a disabled state. The clock receiving circuit 110 may maintain the logic levels of the first internal clock signal pair ICK1 and IBCK1 at the same logic level, i.e., at a high logic level. The clock buffer 910 may differentially amplify the first and second data clock signals WCK and WCKB to generate the first and second buffered clock signals BCK and BCKB. In FIG. 13, The delay in generating the first and second buffered clock signals BCK and BCKB from the first and second data clock signals WCK and WCKB is assumed to be negligible. The first and second buffered clock signals BCK and BCKB may have logic levels corresponding to logic levels of the first and second data clock signals WCK and WCKB, respectively. When the write signal WT is enabled, the enable control circuit 1010 may disable the second driver enable signal DEN2, and the second driver circuit 1030 may be partially activated to set a logic level of the first complementary internal clock signal IBCK1 to a low logic level. Accordingly, the first internal clock signal pair ICK1 and IBCK1 may be set to different logic levels, and a flat section of the first internal clock signal pair ICK1 and IBCK1 may begin.

At t11, the first and second data clock signals WCK and WCKB may begin toggling. The first and second data clock signals WCK and WCKB may include a 2tCK preamble, and the 2tCK preamble may be maintained from t11 to t14. When the first and second buffered clock signals BCK and BCKB begin toggling in response to the first and second data clock signals WCK and WCKB, the enable control circuit 1010 may enable the first driver enable signal DEN1 at t12, which is the timing of a first falling edge of the first buffered clock signal BCK, and may enable the second driver enable signal DEN2 in response to the first driver enable signal DEN1. Once the first and second driver circuits 1020 and 1030 are fully activated, the first driver circuit 1020 may toggle the first internal clock signal ICK1 by inverting the first buffered clock signal BCK, and the second driver circuit 1030 may toggle the first complementary internal clock signal IBCK1 by inverting the second buffered clock signal BCKB. Accordingly, the clock receiving circuit 110 may toggle the first internal clock signal pair ICK1 and IBCK1 after a time corresponding to 1tCK has elapsed from a rising edge of the first buffered clock signal BCK. Therefore, the clock receiving circuit 110 may convert the 2tCK preamble of the first and second data clock signals WCK and WCKB into a 1tCK flat section and a 1tCK preamble of the first internal clock signal pair ICK1 and IBCK1. The 1tCK flat section may occur from t11 to t13, and the 1tCK preamble may occur from t13 to t14. The flat section of the first internal clock signal pair ICK1 and IBCK1 may be maintained from the time the write signal WT is enabled to t13, and because an additional flat section of 1tCK is secured, the write clock divider circuits 141 and 161 may be given sufficient time to be reset. After t14, the first internal clock signal pair ICK1 and IBCK1 may toggle according to bodies of the first and second data clock signals WCK and WCKB, or the first and second buffered clock signals BCK and BCKB.

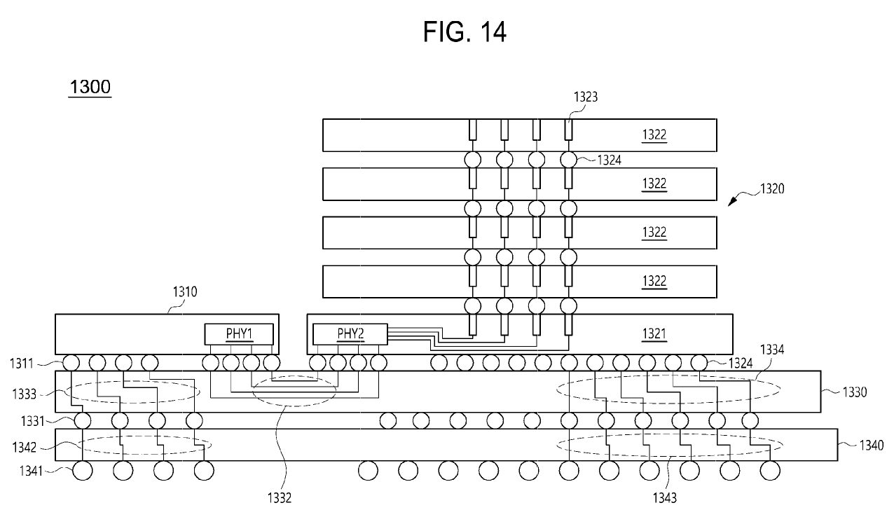

FIG. 14 illustrates a configuration of a semiconductor system 1300 in an embodiment of the present disclosure. Referring to FIG. 14, the semiconductor system 1300 may include a host device 1310 and a memory apparatus 1320. The host device 1310 may be a master device that controls the memory apparatus 1320 so that the memory apparatus 1320 can perform various operations. The host device 1310 may access the memory apparatus 1320 to write data to the memory apparatus 1320 during a write operation, and read data stored in the memory apparatus 1320 during a read operation. For example, the host device 1310 may include at least one or a combination of two or more of a Central Processing Unit (CPU), a Graphic Processing Unit (GPU), a Multi-Media Processor (MMP), a Digital Signal Processor (DSP), an Application Processor (AP), a Data Processing Unit (DPU), a Neural Processing Unit (NPU), and a System-on-Chip (SoC). The memory apparatus 1320 may be controlled by the host device 1310 to store data transmitted from the host device 1310, and to output data stored in the memory apparatus 1320 to the host device 1310. For example, the memory apparatus 1320 may be a High Bandwidth Memory (HBM).

The host device 1310 may include an interface circuit PHY1. The host device 1310 may be coupled to the memory apparatus 1320 through the interface circuit PHY1, and may transmit various signals to and receive various signals from the memory apparatus 1320 through the interface circuit PHY1. The host device 1310 may correspond to the external device. For example, the host device 1310 may transmit command/address signals, a system clock signal pair, a data clock signal pair WCK and WCKB, strobe signals, and data to the memory apparatus 1320 through the interface circuit PHY1. The host device 1310 may receive strobe signals and data transmitted from the memory apparatus 1320 through the interface circuit PHY1. The memory apparatus 1320 may include a logic die 1321 and a plurality of memory dies 1322. The plurality of memory dies 1322 may be sequentially stacked on the logic die 1321, and may be electrically connected to each other through through vias 1323 that are formed through the logic die 1321 and the plurality of memory dies 1322, respectively. The logic die 1321 may relay data communication between the host device 1310 and the plurality of memory dies 1322. The logic die 1321 may include an interface circuit PHY2 to connect the host device 1310 with the plurality of memory dies 1322. The interface circuit PHY2 may convert signals transmitted from the host device 1310 into signals suitable for use in the memory apparatus 1320, and transmit the converted signals to the plurality of memory dies 1322. The interface circuit PHY2 may also convert signals output from the plurality of memory dies 1322 into signals suitable for use in the host device 1310, and transmit the converted signals to the host device 1310. The interface circuit PHY2 of the logic die 1321 may include the configuration of the memory apparatus 100 shown in FIG. 1. To support high bandwidth, the memory apparatus 1320 may be coupled to the host device 1310 through a large number of signal transmission lines, and thus may be fabricated in a structure in which the memory apparatus 1320 is disposed with the host device 1310 on a single substrate.

The semiconductor system 1300 may further include an interposer 1330 and a package substrate 1340. The interposer 1330 may be disposed on the package substrate 1340, and the host device 1310 and the memory apparatus 1320 may be disposed on the interposer 1330. The host device 1310 may be disposed on a first region (the left region in FIG. 14) of the interposer 1330, and the memory apparatus 1320 may be disposed on a second region (the right region in FIG. 14) of the interposer 1330. The package substrate 1340, the interposer 1330, the host device 1310, and the memory apparatus 1320 may be packaged as a single package. The package substrate 1340 may be coupled to an external device through package balls 1341, and signal paths 1342 and 1343 may be formed in the package substrate 1340 to connect the interposer 1330 with the package balls 1341. The interposer 1330 may be electrically connected to the signal paths 1342 and 1343 of the package substrate 1340 through bumps 1331.

The interposer 1330 may include a signal path 1332 configured to connect the host device 1310 and the memory apparatus 1320. The signal path 1332 may connect the interface circuit PHY2 of the logic die 1321 and the interface circuit PHY1 of the host device 1310. In addition, the interposer 1330 may include signal paths 1333 and 1334 configured to connect the host device 1310 and the memory apparatus 1320 to the package substrate 1340. The host device 1310 may be coupled to the signal path 1333 of the interposer 1330 through micro-bumps 1311, and the memory apparatus 1320 may be coupled to the signal path 1334 of the interposer 1330 through micro-bumps 1324. The logic die 1321 may be coupled to the signal path 1334 of the interposer 1330 through the micro-bumps 1324, and the plurality of memory dies 1322 may be sequentially stacked on the logic die 1321 through the micro-bumps 1324. The micro-bumps 1324 may electrically connect the through vias of the logic die 1321 and the through vias between the plurality of memory dies 1322.

The signal path 1332 of the interposer 1330, which connects the interface circuits PHY2 and PHY1 of the logic die 1321 and the host device 1310, respectively, may be a signal transmission line, link, bus, or channel between the host device 1310 and the memory apparatus 1320. For example, the data clock signal pair WCK and WCKB and the first and second data DQ1 and DQ2, shown in FIG. 1, may be transmitted between the host device 1310 and the memory apparatus 1320 through the signal path 1332. The signal path 1333 of the interposer 1330, which connects the host device 1310 to the package substrate 1340, may be a signal transmission line, link, bus, or channel through which the host device 1310 communicates with an external device. The signal path 1334 of the interposer 1330, which connects the logic die 1321 to the package substrate 1340, may be a direct access path through which the external device directly accesses the memory apparatus 1320.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the provided descriptions. All changes within the meaning and range of equivalency of the claims are included within their scope.

What is claimed is:

1. A semiconductor apparatus, comprising:
a clock receiving circuit configured to receive a first data clock signal and a second data clock signal, and configured to generate a first internal clock signal pair and a second internal clock signal pair;
a first clock distribution circuit configured to transmit the first internal clock signal pair;
a second clock distribution circuit configured to divide a frequency of the second internal clock signal pair to generate a plurality of read clock signals, and configured to transmit the plurality of read clock signals;
a first data receiving circuit configured to receive the first internal clock signal pair from the first clock distribution circuit, configured to divide a frequency of the first internal clock signal pair to generate a first plurality of write clock signals, and configured to receive first data in synchronization with the first plurality of write clock signals; and
a first data output circuit configured to receive the plurality of read clock signals from the second clock distribution circuit, and configured to output the first data based on the plurality of read clock signals.

2. The semiconductor apparatus of claim 1, wherein a propagation distance of the first internal clock signal pair through the first clock distribution circuit is longer than a sum of a distance over which the first internal clock signal pair propagates from the clock receiving circuit to an input terminal of the first clock distribution circuit and a distance over which the first internal clock signal pair propagates from an output terminal of the first clock distribution circuit to the first data receiving circuit.

3. The semiconductor apparatus of claim 1, wherein the first clock distribution circuit includes a plurality of repeaters configured to repeat the first internal clock signal pair.

4. The semiconductor apparatus of claim 1, wherein the first data receiving circuit comprises:
a first write clock divider circuit configured to receive the first internal clock signal pair from the first clock distribution circuit, and configured to divide a frequency of the first internal clock signal pair to generate the first plurality of write clock signals; and
a first data receiver configured to receive the first data, which is transmitted through a first data bus in synchronization with the first plurality of write clock signals, and configured to generate first input data.

5. The semiconductor apparatus of claim 4, wherein the first internal clock signal pair includes a first internal clock signal and a first complementary internal clock signal, and
the first write clock divider circuit comprises:
a phase averaging circuit configured to invert the first internal clock signal to change a voltage level of the first complementary internal clock signal, and configured to invert the first complementary internal clock signal to change a voltage level of the first internal clock signal; and
a clock divider circuit configured to divide a frequency of the first internal clock signal and the first complementary internal clock signal to generate the first plurality of write clock signals.

6. The semiconductor apparatus of claim 1, further comprising a second data receiving circuit configured to receive the first internal clock signal pair from the first clock distribution circuit, configured to divide a frequency of the first internal clock signal pair to generate a second plurality of write clock signals, and configured to receive second data in synchronization with the second plurality of write clock signals.

7. The semiconductor apparatus of claim 6, wherein the second data receiving circuit comprises:
a second write clock divider circuit configured to receive the first internal clock signal pair from the first clock distribution circuit, configured to divide a frequency of the first internal clock signal pair to generate the second plurality of write clock signals; and
a second data receiver configured to receive the second data, which is transmitted through a second data bus in synchronization with the second plurality of write clock signals, and configured to generate second input data.

8. The semiconductor apparatus of claim 1, wherein a propagation distance of the plurality of read clock signals through the second clock distribution circuit is longer than a sum of a distance over which the second internal clock signal pair propagates from the clock receiving circuit to an input terminal of the second clock distribution circuit and a distance over which the plurality of read clock signals propagate from an output terminal of the second clock distribution circuit to the first data output circuit.

9. The semiconductor apparatus of claim 1, wherein the second clock distribution circuit comprises:
a read clock divider circuit configured to divide a frequency of the second internal clock signal pair to generate the plurality of read clock signals; and
a plurality of repeaters configured to repeat the plurality of read clock signals.

10. The semiconductor apparatus of claim 9, wherein the read clock divider circuit comprises:
a clock divider circuit configured to divide a frequency of the second internal clock signal pair to generate the plurality of read clock signals; and
a phase adjustment circuit configured to adjust phases of the plurality of read clock signals based on a duty control signal.

11. The semiconductor apparatus of claim 1, wherein the first data output circuit includes a first data transmitter configured to output first output data as the first data to a first data bus in synchronization with the plurality of read clock signals.

12. The semiconductor apparatus of claim 1, further comprising a second data output circuit configured to receive the plurality of read clock signals from the second clock distribution circuit, and configured to output second data based on the plurality of read clock signals.

13. The semiconductor apparatus of claim 12, wherein the second data output circuit includes a second data transmitter configured to output second output data as the second data to a second data bus in synchronization with the plurality of read clock signals.

14. The semiconductor apparatus of claim 1, wherein the clock receiving circuit comprises:
a clock buffer configured to differentially amplify the first and second data clock signals to generate a first buffered clock signal and a second buffered clock signal;
a write clock driver circuit configured to, after a write signal is enabled, set logic levels of the first internal clock signal pair to be opposite to each other until the first buffered clock signal and the second buffered clock signal toggle at least once, and configured to change the logic levels of the first internal clock signal pair according to logic levels of the first buffered clock signal and the second buffered clock signal after the first buffered clock signal and the second buffered clock signal toggle at least once; and
a read clock driver circuit configured to change logic levels of the second internal clock signal pair according to logic levels of the first buffered clock signal and the second buffered clock signal when a read signal is enabled.

15. A semiconductor apparatus, comprising:
a clock receiving circuit configured to receive a first data clock signal and a second data clock signal, and configured to generate a first internal clock signal pair and a second internal clock signal pair;
a first clock distribution circuit configured to transmit the first internal clock signal pair;
a first data receiving circuit configured to receive the first internal clock signal pair from the first clock distribution circuit, configured to divide a frequency of the first internal clock signal pair to generate a first plurality of write clock signals, and configured to receive first data based on the first plurality of write clock signals; and
a second data receiving circuit configured to receive the first internal clock signal pair from the first clock distribution circuit, configured to divide a frequency of the first internal clock signal pair to generate a second plurality of write clock signals, and configured to receive second data based on the second plurality of write clock signals.

16. The semiconductor apparatus of claim 15, wherein the first data receiving circuit comprises:
a first write clock divider circuit configured to receive the first internal clock signal pair from the first clock distribution circuit, and configured to divide a frequency of the first internal clock signal pair to generate the first plurality of write clock signals; and
a first data receiver configured to receive the first data, which is transmitted through a first data bus in synchronization with the first plurality of write clock signals, and configured to generate first input data.

17. The semiconductor apparatus of claim 15, wherein the second data receiving circuit comprises:
a second write clock divider circuit configured to receive the first internal clock signal pair from the first clock distribution circuit, configured to divide a frequency of the first internal clock signal pair to generate the second plurality of write clock signals; and
a second data receiver configured to receive the second data, which is transmitted through a second data bus in synchronization with the second plurality of write clock signals, and configured to generate second input data.

18. The semiconductor apparatus of claim 15, further comprising:
a second clock distribution circuit configured to receive the second internal clock signal pair from the clock receiving circuit, configured to divide a frequency of the second internal clock signal pair to generate a plurality of read clock signals, and configured to transmit the plurality of read clock signals; and
a first data output circuit configured to receive the plurality of read clock signals from the second clock distribution circuit, and configured to output the first data based on the plurality of read clock signals.

19. The semiconductor apparatus of claim 18, wherein the second clock distribution circuit comprises:
a read clock divider circuit configured to divide a frequency of the second internal clock signal pair to generate the plurality of read clock signals; and
a plurality of repeaters configured to repeat the plurality of read clock signals.

20. The semiconductor apparatus of claim 18, wherein the first data output circuit includes a first data transmitter configured to output first output data as the first data to a first data bus in synchronization with the plurality of read clock signals.

21. The semiconductor apparatus of claim 19, further comprising a second data output circuit configured to receive the plurality of read clock signals from the second clock distribution circuit, and configured to output the second data based on the plurality of read clock signals.

22. The semiconductor apparatus of claim 21, wherein the second data output circuit includes a second data transmitter configured to output second output data as the second data to a second data bus in synchronization with the plurality of read clock signals.
